(19) United States
(12) Patent Application Publication
(10) Pub. No.: US 2019/0155355 A1
(43) Pub. Date: May 23, 2019

(54) NETWORK SENSING DEVICE AND POWER MANAGEMENT METHOD THEREOF

(71) Applicant: INDUSTRIAL TECHNOLOGY RESEARCH INSTITUTE, HSIN-CHU (TW)

(72) Inventors: SHUI-AN WEN, Taichung (TW); Shing-Wu Tung, Taipei (TW); Chun-Chih Chen, Taipei (TW); Shih-Tung Huang, Tainan (TW)

(21) Appl. No.: 15/975,824

(22) Filed: May 10, 2018

(30) Foreign Application Priority Data
Nov. 17, 2017 (TW) 106139976

(51) Int. Cl. G06F 1/32; G06F 1/30; H03K 23/40; H04W 52/02

(52) U.S. Cl. CPC G06F 1/3203; H04W 52/029; H03K 23/40; G06F 1/30

(57) ABSTRACT

A network sensing device is provided, which may include an active scheduling circuit and a sensor. The active scheduling circuit may operate regularly, and periodically generate a trigger signal. The sensor may include a power management circuit and a sensor circuit. The power management circuit may be coupled to the active scheduling circuit. The sensor circuit may be coupled to the power management circuit. The trigger signal may trigger the power management circuit, and the power management circuit may switch the sensor from a sleep mode to an active mode; the sensor circuit may collect the environmental information in the active mode, and the sensor may return to the sleep mode after the environmental information is saved.

### CROSS REFERENCE TO RELATED APPLICATION

This non-provisional application claims priority under 35 U.S.C. § 119(a) on Patent Application No(s). 106139976 filed in Taiwan, R.O.C. on Nov. 17, 2017, the entirety of which is incorporated by reference herein.

### TECHNICAL FIELD

The present application relates to a network sensing device and a power management method.

### BACKGROUND OF THE INVENTION

Internet of Things (IoT) is created by the advancement of technology progress. IoT provides a great change for human life, and now becomes the trend of future development. The network sensing devices of IoT can collect a variety of environmental information, such as temperature, humidity, CO, CO₂, O₂, gravity, PM2.5, and light. The network sensing devices become the core elements of IoT owing to the information will be analyzed and applied.

In order to collect the variety environmental information, the wireless radio module and the other elements of the network sensing devices should be enabled frequently to transfer environmental information to other devices. The power consumption of the network sensing devices is increased.

However, most of the power of the network sensing device is provided by batteries. The network sensing device fails to work when the electricity of the batteries has run down and the life of the network sensing device is shortened. This is not convenient for the requirements of real world applications.

If the network sensing device is equipped with a high-capacity battery, the life of the network sensing device can be extended. However, the weight and the volume of the network sensing device are increased, and the cost of the network sensing device is increased, too.

Therefore, it is an important issue to provide a network sensing device of IoT for effectively improving the limitations of existing network sensing devices of IoT.

### SUMMARY OF THE INVENTION

According to the exemplary embodiments of the present application, a network sensing device and a power-saving method are provided, which may effectively improve the limitations of the existing network sensors of IoT.

In an embodiment of the present application, a network sensing device is provided. The network sensing device comprises an active scheduling circuit and a sensor. The active scheduling circuit operates regularly, and generates a trigger signal periodically. The sensor includes a power management circuit and a sensor circuit. The power management circuit is coupled to the active scheduling circuit. The sensor circuit is coupled to the power management circuit. The trigger signal triggers the power management circuit, and the power management circuit enables the sensor to switch from a sleep mode to an active mode. The sensor circuit collects an environmental information in the active mode, and the sensor returns to the sleep mode after the environmental information is stored.

In another embodiment of the present application, a power management method is provided. The power management method comprises the following steps: generating a trigger signal periodically by an active scheduling circuit, and the active scheduling circuit operating regularly; triggering the power management circuit of a sensor by the trigger signal, to have the sensor being switched from a sleep mode to an active mode; collecting an environmental information through a sensor circuit of the sensor; and after storing the environmental information, the sensor returning to the sleep mode.

Yet in another embodiment of the present application, a network sensing device is provided. The network sensing device includes an active scheduling circuit and a sensor. The active scheduling circuit operates regularly. The sensor includes a power management circuit, a passive scheduling circuit, and a wireless radio circuit. The power management circuit is coupled to the active scheduling circuit. The passive scheduling circuit is coupled to the active scheduling circuit. The wireless radio circuit is coupled to the passive scheduling circuit. A trigger signal generated by the active scheduling circuit periodically triggers the sensor, to have the sensor being switched from a sleep mode to an active mode and updating a scheduling status of the passive scheduling circuit. The sensor circuit collects an environmental information in the active mode, and returns to the sleep mode after the environmental information is stored. When the scheduling status satisfies a scheduling condition, the passive scheduling circuit enables the wireless radio circuit to have the sensor entering a broadcast mode.

The foregoing will become better understood from a careful reading of a detailed description provided herein below with appropriate reference to the accompanying drawings.

### BRIEF DESCRIPTION OF THE DRAWINGS

FIG. 1 illustrates a network sensing device in accordance with a first embodiment of the present application.

FIG. 2 illustrates mode operations of a network sensing device in accordance with the first embodiment of the present application.

FIG. 3 illustrates a flow chat in accordance with the first embodiment of present application.

FIG. 4 illustrates a block diagram of a network sensing device according to a second embodiment of the present application.

FIG. 5 illustrates mode operations of the network sensing device in accordance with the second embodiment of the present application.

FIG. 6A illustrates a first flow chart according to the second embodiment of the present application.

FIG. 6B illustrates a second flow chart according to the second embodiment of the present application.

FIG. 7 illustrates a block diagram according to a third embodiment of the present application.

FIG. 8 illustrates a flow chart according to the third embodiment of the present application.

### DESCRIPTION OF THE PREFERRED EMBODIMENT

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

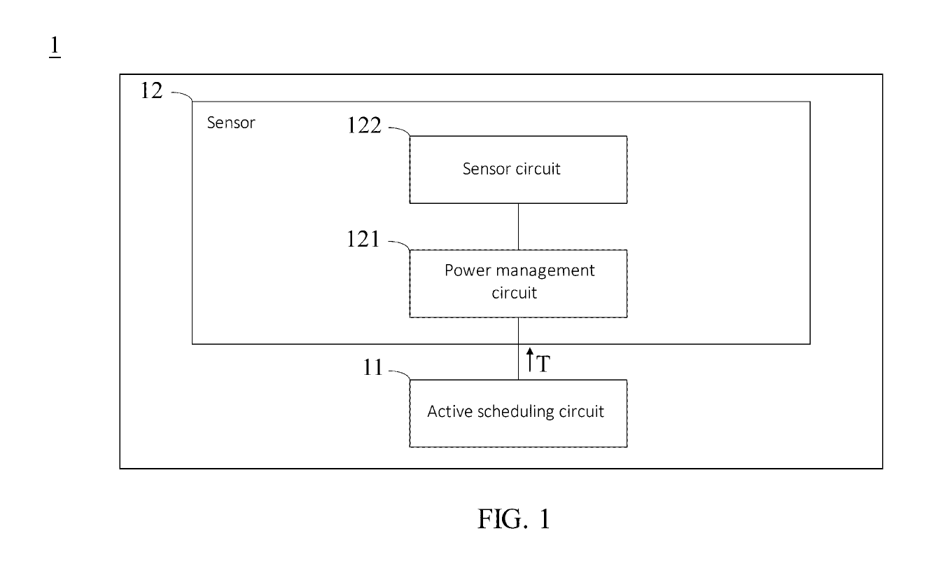

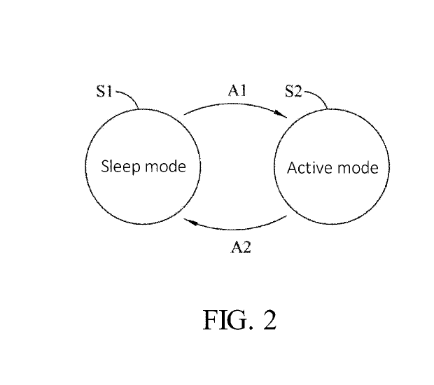

Please refer to FIGS. 1 and 2. FIG. 1 illustrates a network sensing device in accordance with a first embodiment of the present application. FIG. 2 illustrates mode operations of the network sensing device in accordance with the first embodiment of the present application. As shown in FIG. 1, a network sensing device 1 could include an active scheduling circuit 11 and a sensor 12. The active scheduling circuit 11 could also be called a persistent active scheduling circuit.

The active scheduling circuit 11 operates regularly and generates a trigger signal T periodically according to an initial setting. In one embodiment, the active scheduling circuit is a counter, a state machine or a real time clock.

The sensor 12 could include a power management circuit 121 and a sensor circuit 122. The sensor 12 could be a temperature sensor, a humidity sensor, a CO sensor, a CO2 sensor, an O2 sensor, a chemical sensor, a gravity sensor, a PM2.5 sensor, or a light sensor, or any of combinations of the above. The power management circuit 121 is coupled to the active scheduling circuit 11. The sensor circuit 122 is coupled to the power management circuit 121.

The trigger signal T of the active scheduling circuit 11 triggers the power management circuit 121. The power management circuit 121 enables the sensor 12 to be switched from a sleep mode S1 to an active mode S2. The sensor circuit 122 collects the environmental information in the active mode S2. The sensor 12 returns to the sleep mode S1 after the environmental information is stored.

In the sleep mode S1, the power management circuit 122 of the sensor 12 could continue receiving the trigger signal T from the active scheduling circuit 11 and other circuits are all shut down. In other words, the sensor circuit 122 and other peripheral circuits are closed. The sensor 12 doesn't need to enable all functions, and returns to the sleep mode S1 when it finishes the collecting of the environmental information in the active mode S2. Thus, the power consumption should be the lowest. The network sensing device 1 can save more power energies, and the time of using the network sensing device can be lengthened. It is more convenient for meeting the requirements of real world applications.

It is worth to mention here, the wireless radio modules of the existing network sensing devices and other inside elements of the network sensing device need to be enabled frequently and transfer the environmental information to other devices. Thus, the power consumption of the network sensing device is increased. However, according to our embodiment, the active scheduling circuit of the network sensing device can trigger the sensor periodically to switch the sensor form a sleep mode to an active mode. The sensor circuit can collect the environmental information in the active mode and then return to the sleep mode again. The sensor will not be enabled frequently to reduce the power consumption greatly.

Most of the power of the existing network sensing device is provided by batteries. The network sensing device can't work when the electricity of the batteries has run down, and the life time of the network sensing device is shortened. It is not convenient and fails to meet the requirements of the real world applications. However, according to our embodiment, the power consumption of the network sensing device can be reduced greatly. Therefore, the life time of the network sensing device can be lengthened. It is more convenient for meeting the requirements of real world applications.

The existing network sensing device needs to be equipped with high-capacity batteries to lengthen the life time of the network sensing device. The weight and the volume of the existing network sensing device will be increased and the cost of the existing network sensing device will be greatly increased, too. However, according to our embodiments, the power consumption of the network sensing device can be greatly reduced. There is no need for high capacity batteries for the network sensing device. The weight and the volume of the network sensing device can be decreased, and the cost of the network sensing device can be reduced, too.

FIG. 2 illustrates the switching relationships between modes in details. In FIG. 2, in one embodiment, the network sensing device 1 includes 2 modes, namely, the sleep mode S1 and the active mode S2.

In sleep mode S1: the power management circuit 121 of sensor 12 of the network sensing device 1 keep to receive the trigger signal T from the active scheduling circuit 11. The other functions of the network sensing device 1 are shut down. The active scheduling circuit 11 of the network sensing device 1 operates regularly.

When the trigger signal T of the active scheduling circuit 11 of the network sensing device 1 triggers the power management circuit 121 of the sensor 12, the sensor 12 will be switched from sleep mode S1 to active mode S2, as shown by an arrow A1 of FIG. 2.

In active mode S2: the sensor circuit 122 of the sensor 12 collects the environmental information, and the sensor 12 will return to sleep mode S1 when the environmental information is stored, as shown by an arrow A2 of FIG. 2.

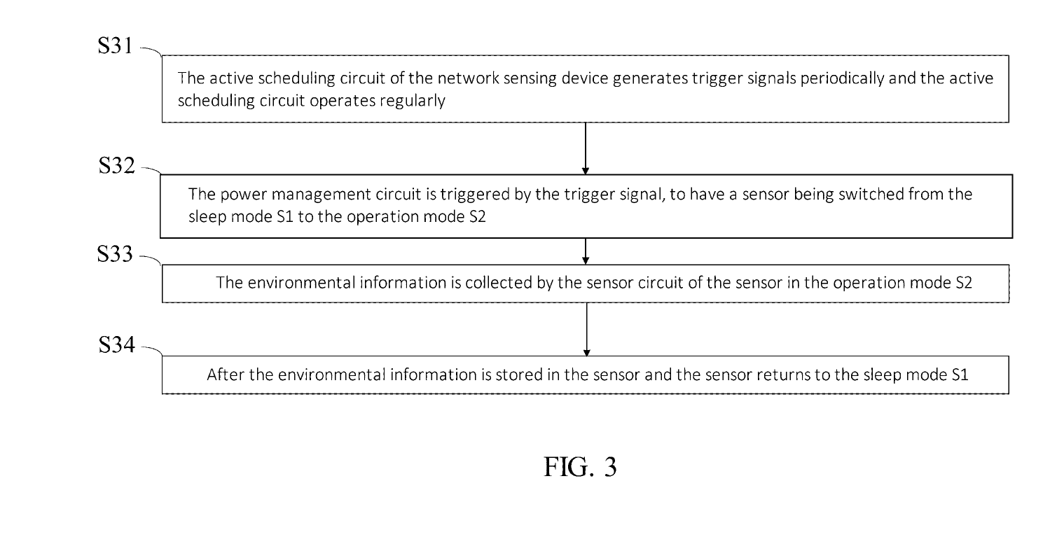

Please refer to FIG. 3. FIG. 3 illustrates the flow chat of the first embodiment of the present application. The power management method of the network sensing device 1 includes the following steps.

Step S31: the active scheduling circuit of the network sensing device generates trigger signals periodically and the active scheduling circuit operates regularly.

Step S32: the power management circuit is triggered by the trigger signal, to have a sensor being switched from the sleep mode S1 to the active mode S2.

Step S33: the environmental information is collected by the sensor circuit of the sensor in the active mode S2.

Step 34: after the environmental information is stored in the sensor, the sensor returns to the sleep mode S1.

The functions of each of elements of the network sensing device 1 can be different according to real applications. The inventive concept in the disclosure may be embodied in various forms without being limited to the exemplary embodiment set forth herein.

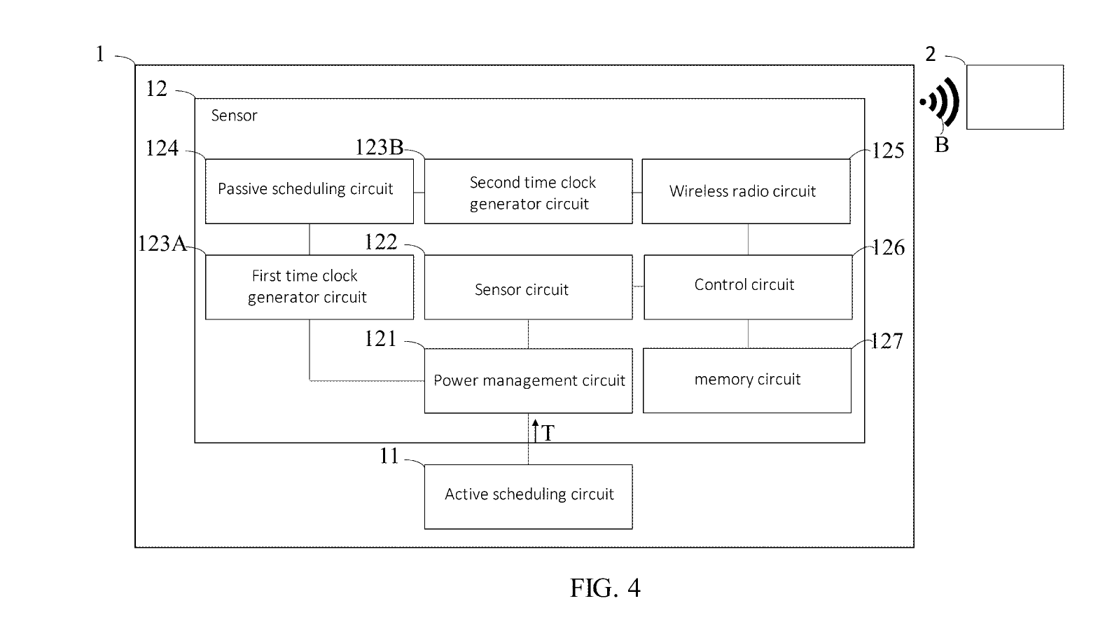

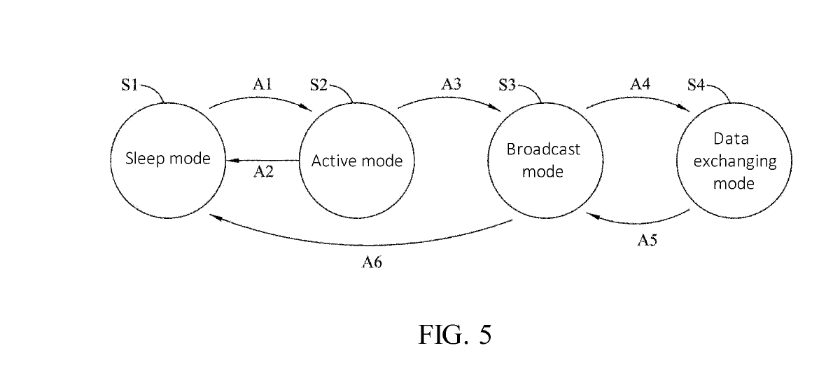

Please refers to FIG. 4 and FIG. 5. FIG. 4 illustrates a block diagram of a network sensing device according to a second embodiment of the present application. FIG. 5 illustrates each mode of the network sensing device according to the second embodiment of the present application. In FIG. 4, the network sensing device 1 may play as a passive device, and exchange data with an active device 2, the network sensing device 1 may include the active scheduling circuit 11 and the sensor 12.

The active scheduling circuit 11 operates regularly and generates a trigger signal T periodically according to an initial setting. In one embodiment, the active scheduling circuit is a counter, a state machine or a real time clock.

The sensor 12 could include the power management circuit 121, the sensor circuit 122, a first time clock generator circuit 123A, a second time clock generator circuit 123B, a passive scheduling circuit 124, a wireless radio circuit 125 a control circuit 126 and a memory circuit 127. The first time clock generator circuit 123A could also be called a first order clock generator circuit. The second time clock generator circuit 123B could also be called a second order clock generator circuit. The wireless radio circuit 125 could also be called RF circuit.

The sensor 12 could be a temperature sensor, a humidity sensor, a CO sensor, a CO2 sensor, an O2 sensor, a chemical sensor, a gravity sensor, a PM2.5 sensor, or a light sensor, or any of combinations of the above. The power management circuit 121 is coupled to the active scheduling circuit 11. The sensor circuit 122 and the first time clock generator circuit 123A are coupled to the power management circuit 121. In one embodiment, the first time clock generator circuit may be, but not limited to a time clock generator, a pulse circuit and a trigger circuit.

The second time clock generator circuit 123B is coupled to the passive scheduling circuit 124. In one embodiment, the second time clock generator circuit may be, but not limited to a time clock generator, a pulse circuit and a trigger circuit.

The wireless radio circuit 125 is coupled to the second time clock generator circuit 123B. In one embodiment, the wireless radio circuit may be, but not limited to a Bluetooth communication module, a Wi-Fi communication module, a Near Field communication module, a ZigBee communication module, a radio identification communication module, an infrared communication module, a Home RF communication module, a Ultra Wide-Band communication module, a 2G communication module, a 3G communication module, a 4G communication module and a 5G communication module.

The control circuit 126 is coupled to the sensor circuit 122, the wireless radio circuit 125 and the memory circuit 127. The control circuit 126 may be, but not limited to a micro-processor (MCU) or a central processing unit (CPU). The memory circuit 127 may be, but not limited to a non-volatile memory and a volatile memory.

The trigger signal T of the active scheduling circuit 11 triggers the power management circuit 121. The power management circuit 121 enables the sensor 12 to be switched from a sleep mode S1 to an active mode S2. The sleep mode S1 could also be called a Hibernation mode in this application. The active mode S2 could also be called an operation mode.

The sensor circuit 122 collects the environmental information in the active mode S2. The first time clock generator circuit 123A is enabled by the power management circuit 121. The first time clock generator circuit 123A triggers the passive scheduling circuit 124 and the scheduling status of the passive scheduling circuit 124 is updated. When the environmental information is stored in the memory circuit 127 by the control circuit 126, the active mode is over, and the sensor 12 returns to the sleep mode S1. In one embodiment, the status is, but not limited to the counter value of the passive scheduling circuit 124.

In sleep mode S1, the power management circuit 121 of sensor 12 of the network sensing device 12 keeps receiving the trigger signal T from the active scheduling circuit 11. Other functions circuits of the network sensing device, including the sensor circuit 122, the first time clock generator circuit 123A, the second time clock generator circuit 123B, the passive scheduling circuit 124, the wireless radio circuit 125 the control circuit 126, the memory circuit 127 and other peripheral circuits are shut down. Thus, the power consumption of the network sensing device can be reduced to the lowest.

When the trigger signal T of the active scheduling circuit 11 of the network sensing device 1 triggers the power management circuit 121 of the sensor 12 again, the sensor 12 will be switched from sleep mode S1 to active mode S2. In active mode S2, the sensor circuit 122 of the sensor 12 collects the environmental information. The first time clock generator circuit 123A is enabled by the power management circuit 121. The passive scheduling circuit 124 is triggered by the first time clock generator circuit 123A to update a scheduling status of the passive scheduling circuit 124. The control circuit 126 will store the environmental information into the memory circuit 127, and the active mode is over. The sensor 12 will return to sleep mode S1. Or, when the scheduling status of the passive scheduling circuit 124 continues to be updated to satisfy a scheduling condition, the passive scheduling circuit will trigger the second time clock generator circuit 123B to enable the wireless radio circuit and the sensor 12 will enter a broadcast mode S3. The broadcast mode S3 could also be called a broadcasting mode. In one embodiment, the scheduling condition is, but not limited to a maximum counter value of the passive scheduling circuit 124.

In broadcast mode S3, the wireless radio circuit 125 transfers a broadcast signal B to the active device 2. When the active device 2 receives the broadcast signal B from the wireless radio circuit 125, the active device 2 can connect with the network sensing device 1 via a network. The sensor 12 enters a data exchanging mode S4. In one embodiment, the active device 2 is, but not limited to a smart phone, a smart watch, a planet computer, a personal assistant and a notebook. The active device can also be the device with wireless interface in the wire network, such as, personal computer or server, and so on.

In the data exchanging mode S4, the wireless radio circuit 125 will transfer the data stored in the memory circuit 127 to the active device 2. After the wireless radio circuit 125 transfers the data stored in the memory circuit 127 to the active device 2, the sensor 12 will return to the broadcast mode S3. The sensor 12 operates in the broadcast mode and continues for a time duration (for example, 300 seconds), to transfer the broadcast signal B to other active devices (not shown in FIG. 4). If there is no other active device connecting with the network sensing device 1 via the network, the sensor 12 will return to the sleep mode S1 after the time duration.

FIG. 5 illustrates mode operations of the network sensing device in accordance with the second embodiment of the present application. In FIG. 5, in one embodiment, the network sensing device 1 includes 4 modes, namely, the sleep mode S1, the active mode S2, the broadcast mode S3 and the data exchanging mode S4.

In sleep mode S1: the power management circuit 121 of sensor 12 of the network sensing device 1 keeps receiving the trigger signal T from the active scheduling circuit 11. Other function circuits of the network sensing device 1 are shut down. The active scheduling circuit 11 of the network sensing device 1 generates trigger signals periodically according to an initial setting. The active scheduling circuit 11 of the network sensing device 1 operates regularly.

When the trigger signal T of the active scheduling circuit 11 of the network sensing device 1 triggers the power management circuit 121 of the sensor 12, the sensor 12 will be switched from sleep mode S1 to active mode S2, as shown by the arrow A1 of FIG. 5.

In active mode S2: the sensor circuit 122 of the sensor 12 collects the environmental information. The power management circuit 121 enables the first time clock generator circuit 123A to trigger the passive scheduling circuit 124 to update the scheduling status. The control circuit 126 of the sensor 12 will store the environmental information in the memory circuit 127, and the active mode is over. The sensor 12 will return to sleep mode S1, as shown by the arrow A2 of FIG. 5. When the scheduling status of the passive scheduling circuit 124 continues to be updated to satisfy a scheduling condition, the passive scheduling circuit 124 will trigger the second time clock generator circuit 123B to enable the wireless radio circuit 125 to have the sensor 12 entering a broadcast mode S3, as shown by an arrow A3 of FIG. 5. In one embodiment, the scheduling condition is, but not limited to a maximum counter value of the passive scheduling circuit 124.

In broadcast mode S3, the wireless radio circuit 125 transfers a broadcast signal B to the active device 2. When the active device 2 receives the broadcast signal B from the wireless radio circuit 125, the active device 2 can connect with the network sensing device 1 via the network. The sensor 12 enters a data exchanging mode S4, as shown by the arrow A4 of FIG. 5.

In the data exchanging mode S4, the wireless radio circuit 125 of the sensor 12 will transfer the data stored in the memory circuit 127 to the active device 2. After the wireless radio circuit 125 transfers the data stored in the memory circuit 127 to the active device 2, the sensor 12 will return to the broadcast mode S3, as shown by an arrow A5 of FIG. 5. The sensor 12 operates in the broadcast mode for a time duration (for example, 300 seconds), to transfer the broadcast signal B to the other active devices. If there is no other active device connecting with the network sensing device 1 via the network, the sensor 12 will return to the sleep mode S1 (as shown by an the arrow A6 of FIG. 5) after the time duration.

The sleep mode S1, the active mode S2, the broadcast mode S3 and the data exchanging mode S4 can be shown as the following table

| | Name | Mode Introduction |
|---|---|---|
| S1 | Sleep Mode | The active scheduling circuit 11 of the network |
| | | sensing device 1 operates regularly and generates |
| | | trigger signals periodically according to an initial |
| | | setting. |
| S2 | Operating | The trigger signal T of the active scheduling circuit |
| | Mode | 11 of the network sensing device 1 triggers the |
| | | power management circuit 121 of the sensor 12 to |
| | | collect the environmental information. |
| S3 | Broadcast | When the scheduling status of the passive scheduling |
| | Mode | circuit 124 satisfies a scheduling condition, the |
| | | active device 2 receives the broadcast signal B from |
| | | the wireless radio circuit 125 of the sensor 12. |
| S4 | Data | The active device 2 connects with the network sensing |
| | Exchanging | device 1 via the network. The wireless radio circuit |
| | Mode | 125 of the sensor 12 transfers the data stored |
| | | in the memory circuit 127 of the sensor 12 to the |
| | | active device 2, |

With the above mechanism, the network sensing device 1 includes the active scheduling circuit 11 and the sensor 12. The network sensing device 1 can dynamically open or shut down the power management circuit 121, the sensor circuit 122, the first time clock generator circuit 123A, the second time clock generator circuit 123B, the passive scheduling circuit 124, the wireless radio circuit 125, the control circuit 126, or the memory circuit 127 of the sensor 12 through the active scheduling circuit 11.

For example, assume that the initial setting of the active scheduling is to generate a trigger signal T per hour. After the power management circuit 121 is triggered by the trigger signal T, the power management circuit 121 may triggers the sensor 12 to enter the active mode S2 from the sleep mode S1. In active mode S2, The sensor circuit 122 collects the environmental information, and the first time clock generator circuit 123A is enabled by the power management circuit 121. The passive scheduling circuit 124 is triggered by the first time clock generator circuit 123A and the counter value of the passive scheduling circuit 124 pluses 1. After the environmental information is stored in the memory circuit 127 of the control circuit 126, the active mode S2 is over and the sensor 12 returns to sleep mode S1. At the moment, the memory circuit 127 already stores one piece of environmental information.

After one hour, the power management circuit 121 is triggered by the trigger signal T again and the power management circuit 121 triggers the sensor 12 to go to the active mode S2 from the sleep mode S1 again. In active mode S2, The sensor circuit 122 collects the environmental information, and the first time clock generator circuit 123A is enabled by the power management circuit 121. The passive scheduling circuit 124 is triggered by the first time clock generator circuit 123A again and the counter value of the passive scheduling circuit 124 pluses 1. After the environmental information is stored in the memory circuit 127 of the control circuit 126, the active mode S2 is over and the sensor 12 returns to sleep mode S1. At the moment, the memory circuit 127 already stores two pieces of environmental information.

After further twenty-two hours, the counter value of the passive scheduling circuit 124 is twenty-four. It is the maximum value of the counter value. At this moment, the memory circuit 127 has stored twenty-four pieces of environmental information. The passive scheduling circuit 124 may enable the wireless radio circuit 125 to enter the broadcast mode S3 and the data exchanging mode S4, and the environmental information in the memory circuit 127 are transferred to the active device 2.

As mentioned above, the sensor circuit 11 of the network sensing device 1 can trigger the sensor 12 periodically. The sensor 12 enters the active mode S2 from the sleep mode S1 and updates the scheduling status of the passive scheduling circuit 124. In active mode S2, the sensor circuit 122 collects the environmental information, and he other elements, for example, the first time clock generator circuit 123A or the second time clock generator circuit 123B, and the wireless radio circuit 125, do not operate most of the time. Thus, even in the active mode S2, most of the elements of the network sensing device do not operate, and this reduces the power consumption of the network sensing device 1 greatly.

According to aforesaid embodiments, the active scheduling circuit of the network sensing device can trigger the sensor periodically to have the sensor entering the active mode S2 from the sleep mode S1 and updating the scheduling status of the passive scheduling circuit. Other elements, for example, the second time clock generator circuit and the wireless radio circuit may stay in their original states without operating. These elements may be enabled to transfer data only when the scheduling status of the passive scheduling circuit satisfies the scheduling condition. The network sensing device can open or shut down each element dynamically. Thus, even in the active mode, most of the elements of the network sensing device do not operate, and the power consumption of the network sensing device 1 is further reduced.

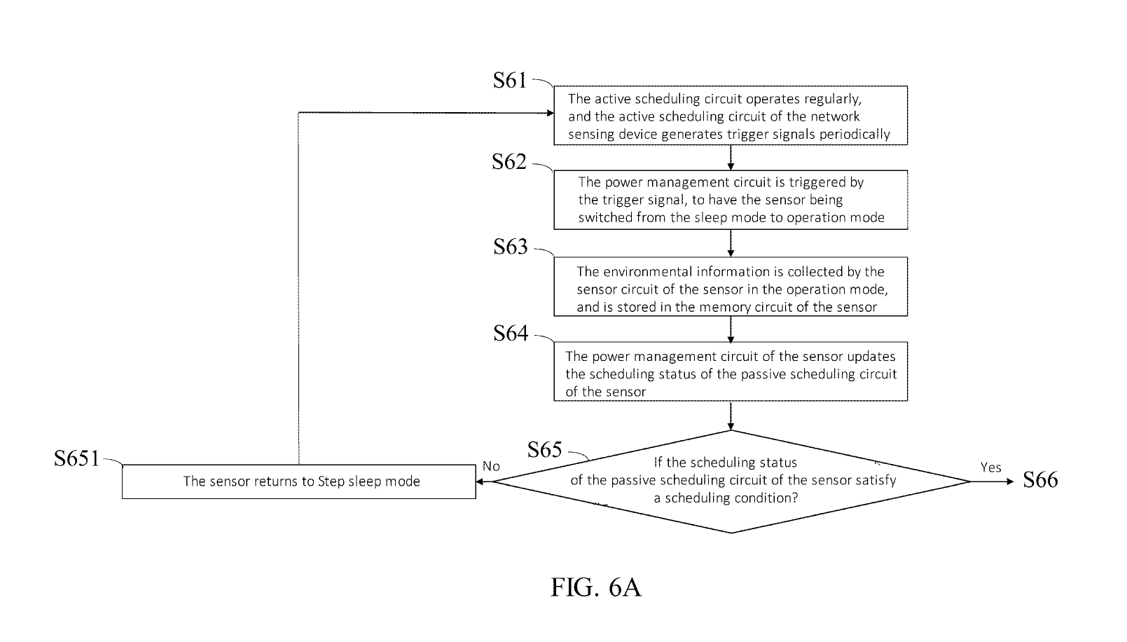

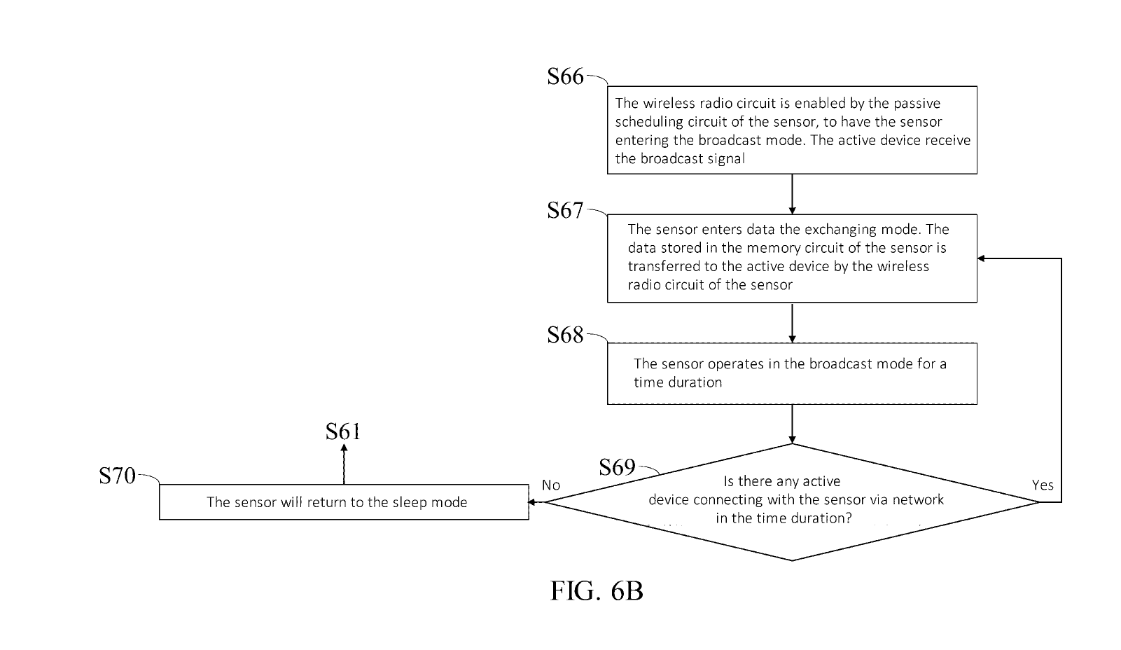

Please refer to FIG. 6A and FIG. 6B. FIG. 6A illustrates a first flow chart according to the second embodiment of the present application. FIG. 6B illustrates a second flow chart according to the second embodiment of the present application. According to one embodiment, the power management method of the network sensing device 1 includes the following steps.

Step S61: the active scheduling circuit operates regularly, and the active scheduling circuit of the network sensing device generates trigger signals periodically. After the step S61, the process of the power management method enters Step S62.

Step S62: the power management circuit is triggered by the trigger signal, to have the sensor being switched from the sleep mode to active mode. After the step S62, the process of the power management method enters Step S63.

Step S63: the environmental information is collected by the sensor circuit of the sensor in the active mode, and is stored in the memory circuit of the sensor. After the step S63, the process of the power management method enters Step S64.

Step S64: the power management circuit of the sensor updates the scheduling status of the passive scheduling circuit of the sensor. After the step S64, the process of the power management method enters Step S65.

Step S65: if the scheduling status of the passive scheduling circuit of the sensor satisfy a scheduling condition? If it is yes, the process of the power management method enters Step S66. If it is not, the process of the power management method enters Step S651.

Step S651: the sensor returns to sleep mode. After the step S651, the process of the power management method enters Step S61.

Step S66: the wireless radio circuit is enabled by the passive scheduling circuit of the sensor, to have the sensor entering the broadcast mode. The active device receive the broadcast signal. After the step S66, the process of the power management method enters Step S67.

Step S67: the sensor enters data the exchanging mode. The data stored in the memory circuit of the sensor is transferred to the active device by the wireless radio circuit of the sensor. After the step S67, the process of the power management method enters Step S68.

Step S68: the sensor operates in the broadcast mode for a time duration. After the step S68, the process of the power management method enters Step S69.

Step S69: Is there any active device connecting with the sensor via the network in the time duration? If it is yes, the process of the power management method enters Step S67. If it is not, the process of the power management method enters Step S70.

Step S70: the sensor will return to the sleep mode. After the step S70, the process of the power management method enters Step S61.

The elements and their functions of the network sensing device 1 can be changed according to real requirements. The inventive concept in the disclosure may be embodied in various forms without being limited to the exemplary embodiment set forth herein.

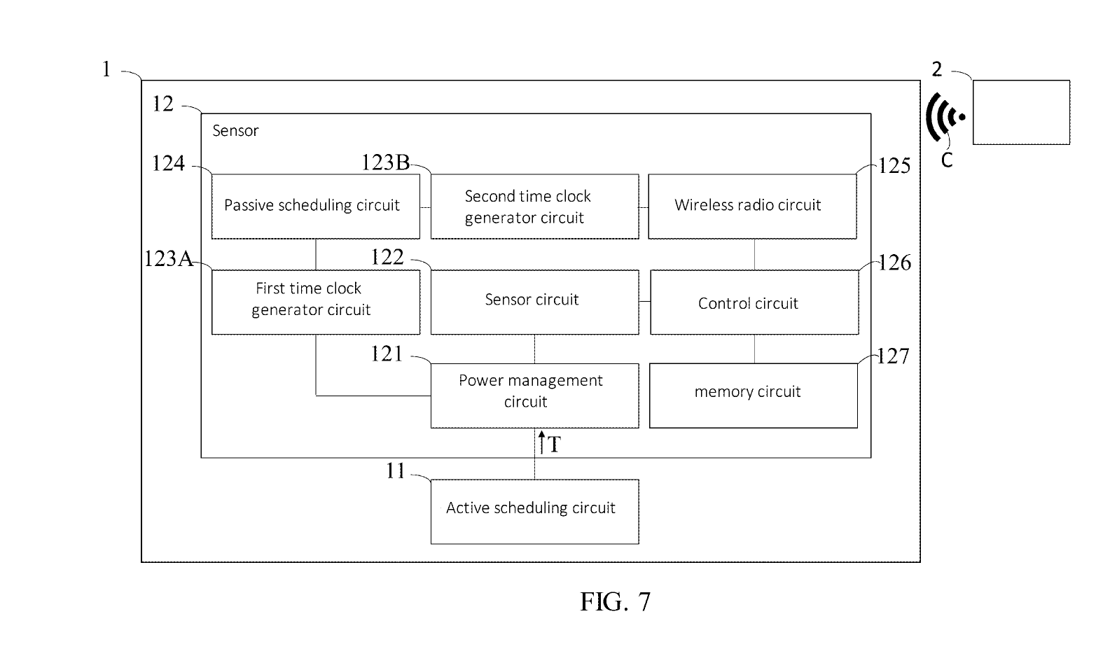

Please refer to FIG. 7. FIG. 7 illustrates a block diagrams according to a third embodiment of the present application. The network sensing device 1 includes the active scheduling circuit 11 and the sensor 12. The sensor 12 could include the power management circuit 121, a the sensor circuit 122, the first time clock generator circuit 123A, the second time clock generator circuit 123B, the passive scheduling circuit 124, the wireless radio circuit 125, the control circuit 126, and the memory circuit 127.

The above elements and their functions are similar to the previous embodiments and are not repeated here. The differences compared to the previous embodiment are as follows. The network sensing device 1 can receive setting command C from the active device 2 to have the active device 2 adjusting the initial setting of the trigger signal T of the active scheduling circuit 11 and the scheduling condition of the passive scheduling circuit 124. Thus, the period of the trigger signal T of the active scheduling circuit 11 and the maximum counter value of the passive scheduling circuit 124 can meet the real requirements much better.

The wireless radio circuit 125 of the sensor connects with the active device 2 via the network. The active device 2 can transfer the setting command C to the wireless radio circuit 125.

Then, the control circuit 126 can adjust the initial setting of the active scheduling circuit 11 and the scheduling condition of the passive scheduling circuit 124 according to the setting command C. The data stored in the memory circuit 127 is transferred to the active device 2 by the wireless radio circuit 125. Finally, the wireless radio circuit 125 disconnects with the active device 2 via the network.

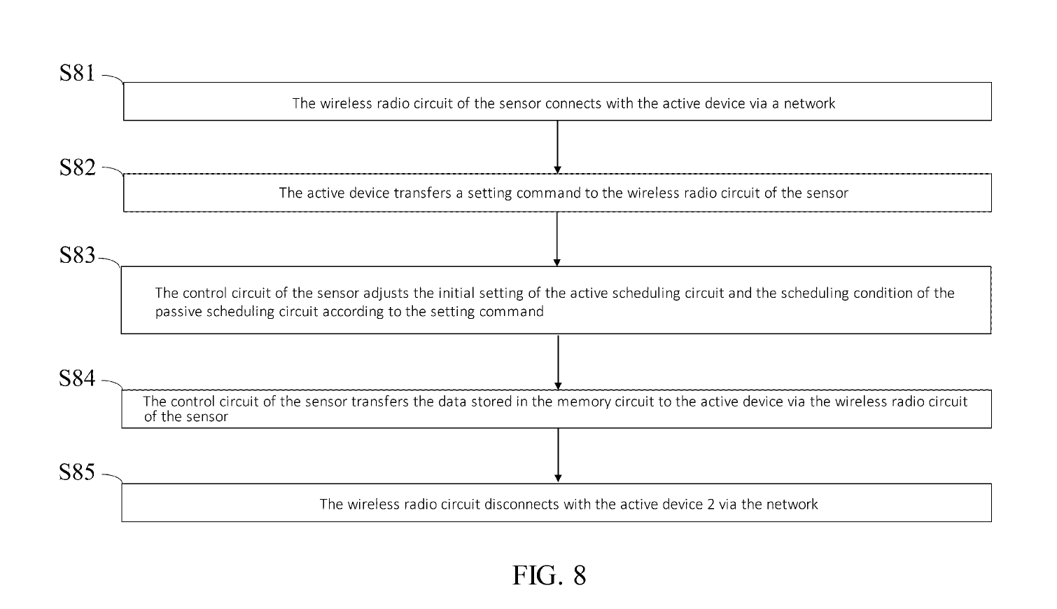

Please refer to FIG. 8. FIG. 8 illustrates a flow chart according to the third embodiment of the present application. According to one embodiment, the power management method of the network sensing device 1 includes the following steps.

Step S81: the wireless radio circuit of the sensor connects with the active device 2 via a network.

Step S82: the active device transfers a setting command to the wireless radio circuit of the sensor.

Step S83: the control circuit of the sensor adjusts the initial setting of the active scheduling circuit and the scheduling condition of the passive scheduling circuit according to the setting command.

Step S84: the control circuit of the sensor transfers the data stored in the memory circuit to the active device via the wireless radio circuit of the sensor.

Step S85: the wireless radio circuit disconnects with the active device 2 via the network.

According the above descriptions, in this embodiment, the active device 2 can transfer the setting command C to the network sensing device 1. The control circuit 126 can adjust the initial setting of the active scheduling circuit 11 and the scheduling condition of the passive scheduling circuit 124. The network sensing device 1 can meet the real requirements much better.

The elements and their functions of the network sensing device 1 can be changed according to real requirements. The inventive concept in the disclosure may be embodied in various forms without being limited to the exemplary embodiment set forth herein.

According to the embodiments disclosed by the present application, the active scheduling circuit of the network sensing device generates trigger signals periodically to trigger the sensor to have the sensor being switched from the sleep mode to active mode. The environmental information is collected by the sensor circuit of the sensor in the active mode. The sensor will return to sleep mode again. The sensor doesn't need to be enabled frequently and the power consumption of the sensor can be reduced greatly.

Again, according to the embodiments disclosed by the present application, the active scheduling circuit of the network sensing device generates trigger signals periodically to trigger the sensor to have the sensor being switched from the sleep mode to active mode. The scheduling status of the passive scheduling circuit is updated. In the active mode, other elements, for example, the second time clock generator circuit and the wireless radio circuit, may stay in their original states without operating. These elements may be enabled to transfer data only when the scheduling status of the passive scheduling circuit satisfies the scheduling condition. Thus, the network sensing device can open or shut down each element dynamically. So, even in active mode, most of the elements of the network sensing device do not operate, and the power consumption of the network sensing device 1 is further reduced.

According to the embodiments disclosed by the present application, the power consumption of the network sensing device is reduced greatly. The life time of the network sensing device is lengthened. It is more convenient for use and meets the requirements of the real world applications much better.

According to our embodiment disclosed by the present application, the power consumption of the network sensing device he is reduced greatly. There is no need for setting high-capacity batteries. The weight and the volume of the network sensing device and the cost of the network sensing device will be reduced. It will be apparent to those skilled in the art that various modifications and variations can be made to the disclosed embodiments. It is intended that the specification and examples be considered as exemplary embodiments only, with a true scope of the disclosure being indicated by the following claims and their equivalents.

What is claimed is:

1. A network sensing device, comprising:
an active scheduling circuit, wherein the active scheduling circuit operates regularly, and generates a trigger signal periodically; and
a sensor, comprising:
a power management circuit, coupled to the active scheduling circuit; and
a sensor circuit, coupled to the power management circuit;
wherein the trigger signal triggers the power management circuit, the power management circuit enables the sensor to switch from a sleep mode to an active mode, the sensor circuit collects an environmental information in the active mode, and the sensor returns to the sleep mode after the environmental information is stored.

2. The network sensing device of claim 1, wherein the sensor is a temperature sensor, a humidity sensor, a CO sensor, a CO₂ sensor, an O₂ sensor, a chemical sensor, a gravity sensor, a PM2.5 sensor, or a light sensor.

3. The network sensing device of claim 1, wherein in the sleep mode, the sensor is shut down, and the power management circuit continues receiving the trigger signal from the active scheduling circuit.

4. The network sensing device of claim 1, wherein the network sensing device further comprises a control circuit and a memory circuit, the control circuit is coupled to the sensor circuit, the memory circuit is coupled to the control circuit, and the control circuit stores the environmental information into the memory circuit.

5. The network sensing device of claim 4, wherein
the sensor further comprises a passive scheduling circuit, the passive scheduling circuit is coupled to the power management circuit, and when the power management circuit is triggered, the power management circuit updates a scheduling status of the passive scheduling circuit.

6. The network sensing device of claim 4, wherein the memory circuit is a non-volatile memory or a volatile memory.

7. The network sensing device of claim 5, wherein the scheduling status is a counter value of the passive scheduling circuit.

8. The network sensing device of claim 5, wherein each of the active scheduling circuit and the passive scheduling circuit is at least one of a counter, a state machine and a real time clock.

9. The network sensing device of claim 5, wherein the sensor further comprises a wireless radio circuit, the wireless radio circuit is coupled to the passive scheduling circuit, and when the scheduling status of the passive scheduling circuit satisfies a scheduling condition, the passive scheduling circuit enables the wireless radio circuit to have the sensor entering a broadcast mode.

10. The network sensing device of claim 9, wherein the scheduling condition is a maximum counter value of the passive scheduling circuit.

11. The network sensing device of claim 9, wherein in the broadcast mode, the wireless radio circuit transfers a broadcast signal to an active device to have the sensor entering a data exchanging mode and connecting with the active device via a network.

12. The network sensing device of claim 11, wherein in the data exchanging mode, the wireless radio circuit transfers the data stored in the memory circuit to the active device.

13. The network sensing device of claim 11, wherein in the data exchanging mode, the sensor operates in the broadcast mode for a time duration, and if there is no other active device connecting with the sensor via the network in the time duration, the sensor returns to the sleep mode after the time duration.

14. The network sensing device of claim 11, wherein the active device transfers a setting command to the wireless radio circuit, the control circuit adjusts an initial setting of the active scheduling circuit and the scheduling condition of the passive scheduling circuit according to the setting command, and transfers the data stored in the memory circuit to the active device through the wireless radio circuit, and the sensor disconnects with the active device via network.

15. The network sensing device of claim 9, wherein the wireless radio circuit is a a Bluetooth communication module, a Wi-Fi communication module, a Near Field communication module, a ZigBee communication module, a radio identification communication module, an infrared communication module, a Home RF communication module, a Ultra Wide-Band communication module, a 2G communication module, a 3G communication module, a 4G communication module, or a 5G communication module.

16. The network sensing device of claim 14, wherein the sensor further comprises a first time clock generator circuit, the passive scheduling circuit is coupled to the power management circuit through the first time clock generator circuit, the power management circuit enables the first time clock generator circuit to trigger the passive scheduling circuit to update the scheduling status.

17. The network sensing device of claim 16, wherein the first time clock generator circuit is one of a time clock generator, a pulse circuit and trigger circuit.

18. The network sensing device of claim 9, wherein the sensor further comprises a second time clock generator circuit, the wireless radio circuit is coupled to the passive scheduling circuit through the second time clock generator circuit, and the passive scheduling circuit enables the second time clock generator circuit to trigger the wireless radio circuit and the sensor to enter the broadcast mode.

19. The network sensing device of claim 18, wherein the second time clock generator circuit is at least one of a time clock generator, a pulse circuit and a trigger circuit.

20. A power management method, comprising:
generating a trigger signal periodically by an active scheduling circuit, and the active scheduling circuit operating regularly;
triggering the power management circuit of a sensor by the trigger signal to have the sensor being switched from a sleep mode to an active mode;
collecting an environmental information through a sensor circuit of the sensor; and
storing the environmental information and the sensor returning to the sleep mode.

21. The power management method of claim 20, wherein storing the environmental information and the sensor returning to the sleep mode further comprises:
shutting down the sensor in the sleep mode, and the power management circuit continuing to receive the trigger signal from the active scheduling circuit.

22. The power management method of claim 20, wherein storing the environmental information and the sensor returning to the sleep mode comprises:
storing the environmental information in a memory circuit of the sensor through a control circuit of the sensor.

23. The power management method of claim 20, further comprising:
updating a scheduling status of a passive scheduling circuit by the power management circuit after the sensor being triggered by the power management circuit.

24. The power management method of claim 23, further comprising:
when the scheduling status of the passive scheduling circuit satisfies a scheduling condition, the passive scheduling circuit enables a wireless radio circuit of the sensor to have the sensor entering a broadcast mode.

25. The power management method of claim 24, further comprising:
wherein in the broadcast mode, the wireless radio circuit transfers a broadcast signal to an active device to have the sensor entering a data exchanging mode when the sensor connects with the active device via a network.

26. The power management method of claim 25, further comprising;
wherein in the data exchanging mode, the wireless radio circuit transfers the data stored in the memory circuit to the active device.

27. The power management method of claim 25, further comprising:
wherein in the data exchanging mode, the sensor operates in the broadcast mode for a time duration, and if there is no other active device connecting with the sensor via the network in the time duration, the sensor returns to the sleep mode after the time duration.

28. The power management method of claim 25, further comprising:
transferring a setting command to the wireless radio circuit by the active device;
adjusting an initial setting of the active scheduling circuit and the scheduling condition of the passive scheduling circuit according to the setting command by the control circuit;
transferring the data stored in the memory circuit to the active device through the wireless radio circuit; and
disconnecting with the active device by the sensor via the network.

29. The power management method of claim 23, further comprising:
enabling a first time clock generator circuit of the sensor through the power management circuit of the sensor to trigger the passive scheduling circuit to update the scheduling status.

30. The power management method of claim 24, further comprising:
enabling a second time clock generator circuit of the sensor through the passive scheduling circuit of the sensor to trigger the wireless radio circuit to have the sensor entering the broadcast mode.

31. A network sensing device, comprising:
an active scheduling circuit, operating regularly; and
a sensor, comprising:
a power management circuit, coupled to the active scheduling circuit;
a passive scheduling circuit, coupled to the active scheduling circuit; and
a wireless radio circuit, coupled to the passive scheduling circuit;
wherein a trigger signal generated by the active scheduling circuit periodically triggers the sensor to have the sensor being switched from a sleep mode to an active mode and updating a scheduling status of the passive scheduling circuit, the sensor circuit collects an environmental information in the active mode; and returns to the sleep mode after the environmental information is stored, and when the scheduling status satisfies a scheduling condition, the passive scheduling circuit enables the wireless radio circuit to have the sensor entering a broadcast mode.

32. The network sensing device of claim 31, wherein the sensor is a temperature sensor, a humidity sensor, a CO sensor, a CO₂ sensor, an O₂ sensor, a chemical sensor, a gravity sensor, a PM2.5 sensor, or a light sensor.

33. The network sensing device of claim 31, wherein in the sleep mode, the sensor is shut down, and the power management circuit continues receiving the trigger signal from the active scheduling circuit.

34. The network sensing device of claim 31, wherein the network sensing device further comprises a control circuit and a memory circuit, the control circuit is coupled to the sensor circuit, the memory circuit is coupled to the control circuit, and the control circuit stores the environmental information into the memory circuit.

35. The network sensing device of claim 31, wherein when the power management circuit is triggered, the power management circuit updates a scheduling status of the passive scheduling circuit.

36. The network sensing device of claim 34, wherein the memory circuit is a non-volatile memory or a volatile memory.

37. The network sensing device of claim 31, wherein the scheduling status is a counter value of the passive scheduling circuit.

38. The network sensing device of claim 31, wherein each of the active scheduling circuit and the passive scheduling circuit is at least one of a counter, a state machine and a real time clock.

39. The network sensing device of claim 31, wherein the scheduling condition is a maximum counter value of the passive scheduling circuit.

40. The network sensing device of claim 31, wherein in the broadcast mode, the wireless radio circuit transfers a broadcast signal to an active device to have the sensor entering a data exchanging mode and connecting with the active device via a network.

41. The network sensing device of claim 40, wherein in the data exchanging mode, the wireless radio circuit transfers the data stored in the memory circuit to the active device.

42. The network sensing device of claim 40, wherein in the data exchanging mode, the sensor operates in the broadcast mode for a time duration, and if there is no other active device connecting with the sensor via network in the time duration, the sensor returns to the sleep mode after the time duration.

43. The network sensing device of claim 40, wherein the active device transfers a setting command to the wireless radio circuit, the control circuit adjusts an initial setting of the active scheduling circuit and the scheduling condition of the passive scheduling circuit according to the setting command, and transfers the data stored in the memory circuit to the active device through the wireless radio circuit, and the sensor disconnects with the active device via network.

44. The network sensing device of claim 31, wherein the wireless radio circuit is a Bluetooth communication module, a Wi-Fi communication module, a Near Field communication module, a ZigBee communication module, a radio identification communication module, an infrared communication module, a Home RF communication module, a Ultra Wide-Band communication module, a 2G communication module, a 3G communication module, a 4G communication module, or a 5G communication module.

45. The network sensing device of claim 31, wherein the sensor further comprises a first time clock generator circuit, the passive scheduling circuit is coupled to the power management circuit through the first time clock generator circuit, and the power management circuit enables the first time clock generator circuit to trigger the passive scheduling circuit to update the scheduling status.

46. The network sensing device of claim 44, wherein the first time clock generator circuit is at least one of a time clock generator, a pulse circuit and a trigger circuit.

47. The network sensing device of claim 31, wherein the sensor further comprising a second time clock generator circuit, the wireless radio circuit is coupled to the passive scheduling circuit through the second time clock generator circuit, and the passive scheduling circuit enables the second time clock generator circuit to trigger the wireless radio circuit to have the sensor entering the broadcast mode.

48. The network sensing device of claim 46, wherein the second time clock generator circuit is at least one of a time clock generator, a pulse circuit and a trigger circuit.
